(19) United States
(12) Patent Application Publication
(10) Pub. No.: US 2024/0297220 A1
(43) Pub. Date: Sep. 5, 2024

(54) SEMICONDUCTOR DEVICE AND METHOD FOR MANUFACTURING

(71) Applicants: Kabushiki Kaisha Toshiba, Tokyo (JP); Toshiba Electronic Devices & Storage Corporation, Tokyo (JP)

(72) Inventors: Masatsugu NAGAI, Nomi Ishikawa (JP); Shingo SATO, Kanazawa Ishikawa (JP)

(21) Appl. No.: 18/236,925

(22) Filed: Aug. 22, 2023

(30) Foreign Application Priority Data
Mar. 3, 2023 (JP) 2023-033003

(51) Int. Cl. H01L 29/08; H01L 21/265; H01L 21/285; H01L 29/45; H01L 29/66; H01L 29/78

(52) U.S. Cl. CPC H01L 29/0856; H01L 21/26513; H01L 21/28518; H01L 29/456; H01L 29/66712; H01L 29/7802

(57) ABSTRACT

A semiconductor device includes a semiconductor layer, first and second electrodes, a control electrode, and a connection region. The semiconductor layer includes first to third semiconductor regions. The connection region is positioned between the first electrode and the first semiconductor region. The connection region includes a compound of a first metallic element and Si, and a compound of Pt and Si. The first metallic element is at least one selected from the group consisting of Ti, V, Cr, Zr, Mo, Hf, Ta, and W. The connection region includes a first part adjacent to an n-type region of the semiconductor layer in a first direction. A peak position of a concentration distribution of the first metallic element in the first direction of the first part is between the n-type region and a peak position of a concentration distribution of Pt in the first direction of the first part.

### CROSS-REFERENCE TO RELATED APPLICATIONS

This application is based upon and claims the benefit of priority from Japanese Patent Application No.2023-033003, filed on Mar. 3, 2023; the entire contents of which are incorporated herein by reference.

### FIELD

Embodiments relate to a semiconductor device and a method for manufacturing.

### BACKGROUND

For example, a connection region to which an electrode is connected is formed in a semiconductor layer of a semiconductor device and includes a silicide. It is desirable to suppress the increase of the electrical resistance (the contact resistance) via the connection region between the electrode and the semiconductor layer.

### BRIEF DESCRIPTION OF THE DRAWINGS

FIG. 1 is a schematic cross-sectional view illustrating a semiconductor device according to an embodiment;

FIG. 2 is a schematic cross-sectional view illustrating a semiconductor device according to a modification of the embodiment;

FIG. 3 is a schematic cross-sectional view illustrating a semiconductor device according to a modification of the embodiment;

FIG. 4 is a schematic cross-sectional view illustrating a semiconductor device according to a modification of the embodiment;

FIG. 5 is a schematic cross-sectional view illustrating a semiconductor device according to a modification of the embodiment;

FIGS. 6A to 6E are schematic cross-sectional views in order of the processes, illustrating a method for manufacturing the semiconductor device according to the embodiment;

### DETAILED DESCRIPTION

A semiconductor device according to one embodiment, includes a semiconductor layer, a first electrode, a second electrode, a control electrode, and a connection region. The semiconductor layer includes a first semiconductor region, a second semiconductor region, and a third semiconductor region. The first semiconductor region is of a first conductivity type. The second semiconductor region contacts the first semiconductor region. The second semiconductor region is of a second conductivity type. The third semiconductor region is located so that a portion of the second semiconductor region is positioned between the first semiconductor region and the third semiconductor region. The third semiconductor region is of the first conductivity type. The first electrode is electrically connected with the first semiconductor region. The second electrode is electrically connected with the third semiconductor region. The control electrode faces the first, second, and third semiconductor regions via an insulating film. The connection region is positioned between the first electrode and the first semiconductor region. The connection region is electrically connecting the first electrode and the first semiconductor region. The connection region includes a compound of a first metallic element and Si, and a compound of Pt and Si. The first metallic element is at least one selected from the group consisting of Ti, V, Cr, Zr, Mo, Hf, Ta, and W. The connection region includes a first part adjacent to an n-type region of the semiconductor layer in a first direction. A peak position of a concentration distribution of the first metallic element in the first direction of the first part is between the n-type region and a peak position of a concentration distribution of Pt in the first direction of the first part.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the following description and drawings, the notations of n⁺, n, n⁻, p⁺, and p indicate relative levels of the impurity concentrations. In other words, a notation marked with “+” indicates that the impurity concentration is relatively greater than that of a notation not marked with either “+” or “−”, and a notation marked with “−” indicates that the impurity concentration is relatively less than that of a notation without any mark. When both a p-type impurity and an n-type impurity are included in each region, these notations indicate relative levels of the net impurity concentrations after the impurities are compensated.

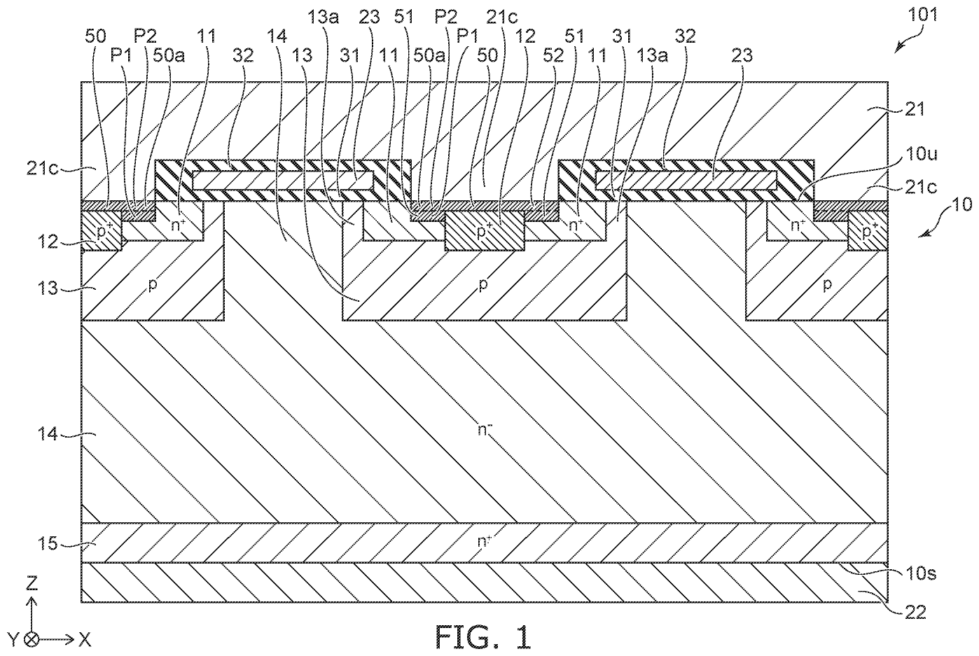

FIG. 1 is a schematic cross-sectional view illustrating a semiconductor device according to an embodiment.

A vertical n-channel MOSFET (Metal-Oxide-Semiconductor Field Effect Transistor) is illustrated as the semiconductor device 101 according to the embodiment in FIG. 1. The semiconductor device 101 includes a semiconductor layer 10, a first electrode 21, a second electrode 22, and multiple control electrodes 23. In the n-channel MOSFET, the semiconductor layer 10 includes multiple source regions 11 (first semiconductor regions), multiple contact regions 12 (fourth semiconductor regions), multiple body regions 13 (second semiconductor regions), a drift region 14 (a third semiconductor region), and a drain region 15 (a fifth semiconductor region).

An XYZ orthogonal coordinate system is used in the description of embodiments. The direction from the second electrode 22 toward the first electrode 21 is taken as a Z-direction. Two mutually-orthogonal directions perpendicular to the Z-direction are taken as an X-direction and a Y-direction. In the description, the direction from the second electrode 22 toward the first electrode 21 is called “up”, and the opposite direction is called “down”. These directions are based on the relative positional relationship between the first electrode 21 and the second electrode 22 and are independent of the direction of gravity.

The second electrode 22 is located at a lower surface 10s of the semiconductor layer 10. The second electrode 22 is, for example, a drain electrode. The second electrode 22 includes a metal such as aluminum, etc.

The drain region 15 contacts the upper surface of the second electrode 22 and is electrically connected with the second electrode 22. In the example, the drain region 15 is of an n-type (an example of a first conductivity type). The drain region 15 is, for example, an n⁺-type drain region.

The drift region 14 is located on the drain region 15 and contacts the drain region 15. The drift region 14 is electrically connected with the second electrode 22 via the drain region 15. In the example, the drift region 14 is of the n-type. The n-type impurity concentration of the drift region 14 is less than the n-type impurity concentration of the drain region 15. The drift region 14 is, for example, an n⁻-type drift region.

The body region 13 is located on a portion of the drift region 14 and contacts the drift region 14. A portion 13a of the body region 13 is positioned between the source region 11 and the drift region 14. In the example, the body region 13 is of a p-type (an example of a second conductivity type). The p-type impurity concentration of the body region 13 is less than the p-type impurity concentration of the contact region 12. The body region 13 is, for example, a p-type body region.

The source region 11 is located on a portion of the body region 13 and contacts the body region 13. The source region 11 is separated from the drift region 14. The source region 11 forms a portion of an upper surface 10u (the surface at the side opposite to the lower surface 10s) of the semiconductor layer 10. Two source regions 11 that are arranged in the X-direction are located on one body region 13. In the example, the source region 11 is of the n-type. The source region 11 is, for example, an n⁺-type source region.

The contact region 12 is located on a portion of the body region 13 and contacts the body region 13. In the example, the contact region 12 is arranged with the source region 11 in the X-direction and contacts the source region 11. The contact region 12 is positioned between two source regions 11 on one body region 13. In the example, the contact region 12 is of the p-type. The contact region 12 is, for example, a p⁺-type region.

The semiconductor regions (the source region 11 to the drain region 15) of the semiconductor layer 10 include silicon as a semiconductor material. Arsenic, phosphorus, or antimony can be used as an n-type impurity. Boron can be used as a p-type impurity.

The control electrode 23 faces the source region 11, the body region 13 (the portion 13a), and the drift region 14 via an insulating film 31. In the example, the insulating film 31 is located on the upper surface 10u of the semiconductor layer 10; and the control electrode 23 is located on the insulating film 31. The upper surface and side surface of the control electrode 23 are covered with an insulating film 32. For example, the control electrode 23 is a gate electrode; and the insulating film 31 is a gate insulating film. The control electrode 23 includes a conductive material such as, for example, polysilicon, etc. The insulating film 31 and the insulating film 32 include insulating materials such as, for example, silicon oxide, silicon nitride, etc.

The first electrode 21 is located on the semiconductor layer 10 and the insulating film 32. The first electrode 21 is electrically connected with the source region 11 and the contact region 12. The first electrode 21 is insulated from the control electrode 23 by the insulating film 32. The first electrode 21 is, for example, a source electrode. The first electrode 21 includes a metal such as titanium, aluminum, etc. The first electrode 21 may include a stacked structure. For example, the first electrode 21 may be a stacked structure that includes a titanium film, a titanium nitride film, a tungsten film, and an aluminum film in this order from below.

Specifically, the first electrode 21 includes multiple contact portions 21c. The contact portion 21c is positioned between two control electrodes 23 (insulating films 32) arranged in the X-direction. A connection region 50 (e.g., a conductive region) to which the contact portion 21c is connected is located at the upper surface 10u side of the semiconductor layer 10. The connection region 50 is positioned between the first electrode 21 and the source region 11 and electrically connects the first electrode 21 and the source region 11. The connection region 50 is positioned between the first electrode 21 and the contact region 12 and electrically connects the first electrode 21 and the contact region 12. The connection region 50 contacts the source region 11, the contact region 12, and the first electrode 21.

The connection region 50 includes a first metallic element, a second metallic element, and silicon. The first metallic element is, for example, at least one selected from the group consisting of titanium (Ti), vanadium (V), chrome (Cr), zirconium (Zr), molybdenum (Mo), hafnium (Hf), tantalum (Ta), and tungsten (W). The second metallic element is platinum (Pt).

For example, the connection region 50 includes a compound (a first silicide) of the first metallic element and silicon (Si) and a compound (a second silicide) of the second metallic element and Si. The connection region 50 may include a first region 51 that includes the first silicide, and a second region 52 that includes the second silicide. The boundary between the first region 51 and the second region 52 is illustrated by a broken line for convenience in the cross-sectional view.

As illustrated in FIG. 1, the connection region 50 includes a first part 50a adjacent to an n-type region of the semiconductor layer 10 in a first direction (e.g., the Z-direction). For example, the first part 50a is adjacent to one of the source region 11 or the contact region 12 that is of the n-type (in the example, the source region 11) in the first direction. In other words, in the example, the first part 50a is a part of the connection region 50 between the source region 11 and the first electrode 21. The first part 50a is a part of the connection region 50 positioned directly above the source region 11 in contact with the source region 11. The first part 50a may be, for example, a part that includes a portion of the first region 51 and a portion of the second region 52.

In the first part 50a, the concentration distribution of the first metallic element in the first direction (e.g., the Z-direction) has a peak (a maximum) at a first position P1. The concentration distribution of the second metallic element in the first direction (e.g., the Z-direction) in the first part 50a has a peak (a maximum) at a second position P2. The position in the first direction of the first position P1 is between the position in the first direction of the second position P2 and the position in the first direction of at least a portion (the n-type region) of the source region 11.

The first region 51 is, for example, a silicide layer of the first metallic element. For example, in the first region 51, the concentration of the first metallic element is greater than the concentration of the second metallic element. For example, the concentration of the first metallic element in the first region 51 is greater than the concentration of the first metallic element in the second region 52.

The second region 52 is, for example, a silicide layer of the second metallic element. For example, in the second region 52, the concentration of the second metallic element is greater than the concentration of the first metallic element. For example, the concentration of the second metallic element in the second region 52 is greater than the concentration of the second metallic element in the first region 51.

The first region 51 may not include the second metallic element or the second silicide. The second region 52 may not include the first metallic element or the first silicide. The scope of “not including a metallic element” includes the case where the metallic element is substantially not included such as when the metallic element is below the detection limit, etc.

At least a portion of the first region 51 is positioned between the source region 11 and the first electrode 21 and contacts the source region 11. For example, the first region 51 (the first silicide) has a Schottky contact with the source region 11. At least a portion of the second region 52 is positioned between the first region 51 and the first electrode 21 and contacts the first region 51 and the first electrode 21.

For example, the first region 51 is positioned directly under a portion of the second region 52. The first region 51 may be formed only on an n-type semiconductor region (in the example, the source region 11) and may not be formed on a p-type semiconductor region (in the example, the contact region 12). However, the first region 51 may contact the contact region 12. In the example, the second region 52 is located between the first region 51 and the first electrode 21; and the first region 51 does not contact the first electrode 21. However, the first region 51 may contact the first electrode 21.

The multiple first regions 51 are located respectively on the multiple source regions 11. The second region 52 is provided continuously on two first regions 51 arranged in the X-direction and on the contact region 12 positioned between the two first regions 51. One contact portion 21c contacts the upper surface of one second region 52. Thus, a portion of the second region 52 is positioned between the contact region 12 and the first electrode 21 and contacts the contact region 12 and the first electrode 21. For example, the second region 52 (the second silicide) has a Schottky contact with the contact region 12. The second region 52 may or may not contact an n-type semiconductor region (in the example, the source region 11).

The first part 50a described above is a part at which the first region 51 and the second region 52 overlap in the first direction. The first position P1 at which the concentration of the first metallic element has a peak in the first part 50a is inside the first region 51. The second position P2 at which the concentration of the second metallic element has a peak in the first part 50a is inside the second region 52.

For example, the concentration (atomic percent) obtained by elemental analysis using energy dispersive X-ray spectrometry (TEM-EDX) of a transmission electron microscope can be used as the concentration of the first metallic element and the concentration of the second metallic element of the connection region 50.

The contact portion 21c, the source region 11, and the contact region 12 each extend in the Y-direction. The connection region 50 extends in the Y-direction along the contact portion 21c, the source region 11, and the contact region 12.

The state in which one region contacts another region may be a state in which the boundary between the regions is not always distinctly observed; the regions may be continuous or may be directly connected (bonded).

An operation of the semiconductor device 101 will now be described.

For example, positive voltages when the voltage of the first electrode 21 is used as a reference (0 V) are applied to the second electrode 22 and the control electrode 23. At this time, an inversion layer (a channel) is formed at the vicinity of the interface between the insulating film 31 of the body region 13 when a larger voltage than the threshold voltage is applied to the control electrode 23. An on-state in which a current flows from the second electrode 22 via the drain region 15, the drift region 14, the body region 13, and the source region 11 toward the first electrode 21 is obtained thereby. When the voltage of the control electrode 23 is not more than the threshold voltage (e.g., 0 V), the channel disappears, and an off-state in which a current substantially does not flow from the second electrode 22 toward the first electrode 21 is obtained. The contact region 12, the body region 13, the drift region 14, and the drain region 15 function as body diodes. In other words, when a negative voltage with respect to the voltage of the first electrode 21 is applied to the second electrode 22, a current flows from the first electrode 21 via the contact region 12, the body region 13, the drift region 14, and the drain region 15 toward the second electrode 22.

The semiconductor device according to the embodiment may be an IGBT (Insulated Gate Bipolar Transistor) or a reverse-conducting IGBT. In other words, for example, a semiconductor region of the second conductivity type may be located on at least a portion of the second electrode 22. The drift region 14 is electrically connected with the second electrode 22 via the semiconductor region of the second conductivity type.

As described above, the connection region 50 includes Pt. For example, Pt can be diffused into the semiconductor regions from the front side of the semiconductor layer 10 by heat treatment. For example, the carrier lifetime in the semiconductor layer 10 can be controlled thereby, and power loss when switching can be suppressed.

Effects of the embodiment will now be described.

When a compound (the second silicide) of Pt and Si and the n-type semiconductor region are in contact, a high energy barrier is formed between the second silicide and the n-type semiconductor region. Therefore, there is a risk that the electrical resistance via the second silicide between the n-type semiconductor region and the electrode connected to the second silicide may become large. In other words, there is a risk that the contact resistance may become large.

In contrast, for example, according to the embodiment, the peak position (the first position P1) of the concentration distribution of the first metallic element in the first direction of the first part 50a of the connection region 50 is between the n-type source region 11 and the peak position (the second position P2) of the concentration distribution of Pt in the first direction of the first part 50a. In such a case, the source region 11 is prevented from contacting the second silicide; and the formation of a high energy barrier between the source region 11 and the second silicide is suppressed. The increase of the contact resistance can be suppressed thereby.

Also, according to the embodiment, for example, the source region 11 contacts the first region 51. That is, the source region 11 contacts the compound (the first silicide) of the first metallic element and Si. Even when the first silicide and the n-type semiconductor region are in contact, an energy barrier is formed between the first silicide and the n-type semiconductor region. However, the energy barrier between the first silicide and the n-type semiconductor region is less than the energy barrier between the second silicide and the n-type semiconductor region. When the source region 11 and the first region 51 are in contact, the increase of the electrical resistance between the source region 11 and the first region 51 is suppressed because the energy barrier between the source region 11 and the first silicide is relatively low. In other words, the increase of the contact resistance can be suppressed.

The energy barrier that is formed between the second silicide and the p-type semiconductor region that contact each other is less than the energy barrier formed between the first silicide and the p-type semiconductor region that contact each other. Therefore, the electrical resistance between the connection region 50 and the contact region 12 can be less when the contact region 12 contacts the second region 52 than when the p-type contact region 12 contacts the first region 51.

For example, the work function of the first silicide is less than the work function of the second silicide. Therefore, the Schottky barrier that is formed by the Schottky contact between the first silicide and the n-type semiconductor region is less than the Schottky barrier formed by the Schottky contact between the second silicide and the n-type semiconductor region. Also, the Schottky barrier that is formed by the Schottky contact between the second silicide and the p-type semiconductor region is less than the Schottky barrier formed by the Schottky contact between the first silicide and the p-type semiconductor region. For example, the work function of the first silicide can be not less than 4.05 eV and not more than 4.85 eV, and more favorably not less than 4.40 eV and not more than 4.80 eV.

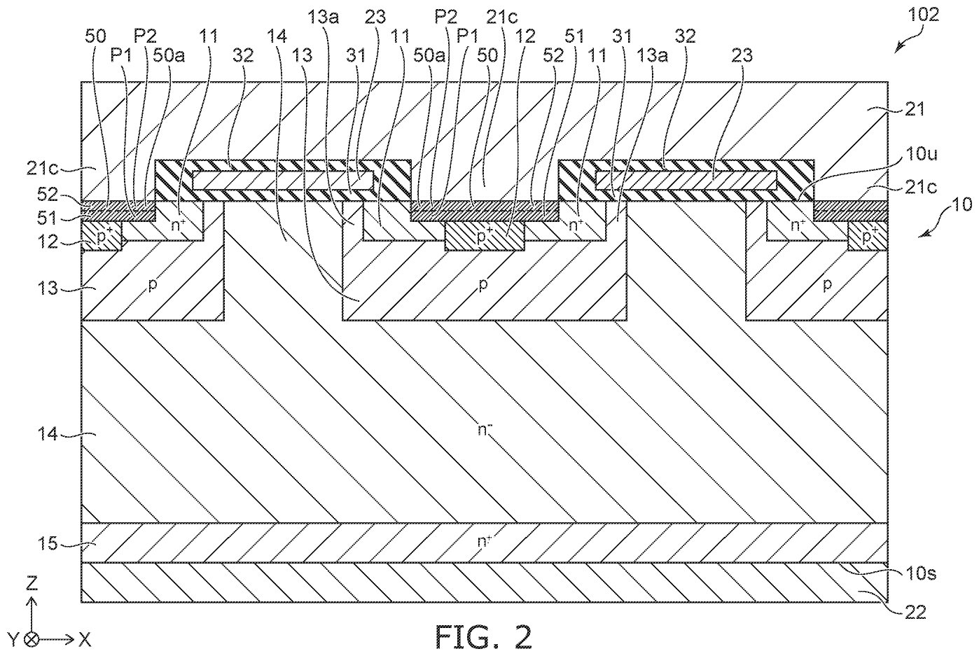

FIG. 2 is a schematic cross-sectional view illustrating a semiconductor device according to a modification of the embodiment.

The arrangement of the first region 51 of the connection region 50 of the semiconductor device 102 according to the embodiment illustrated in FIG. 2 is different from that of the semiconductor device 101 described with reference to FIG. 1.

In the semiconductor device 102, the first region 51 is positioned directly under the entire region of the second region 52. The first region 51 is formed on an n-type semiconductor region (in the example, the source region 11) and on a p-type semiconductor region (in the example, the contact region 12). More specifically, the first region 51 is provided continuously on two source regions 11 arranged in the X-direction and on the contact region 12 between the two source regions 11. The first region 51 contacts the source region 11 and the contact region 12. For example, one second region 52 is located on one first region 51. A portion of the first region 51 is located between the second region 52 and the contact region 12; and the second region 52 may not contact the contact region 12.

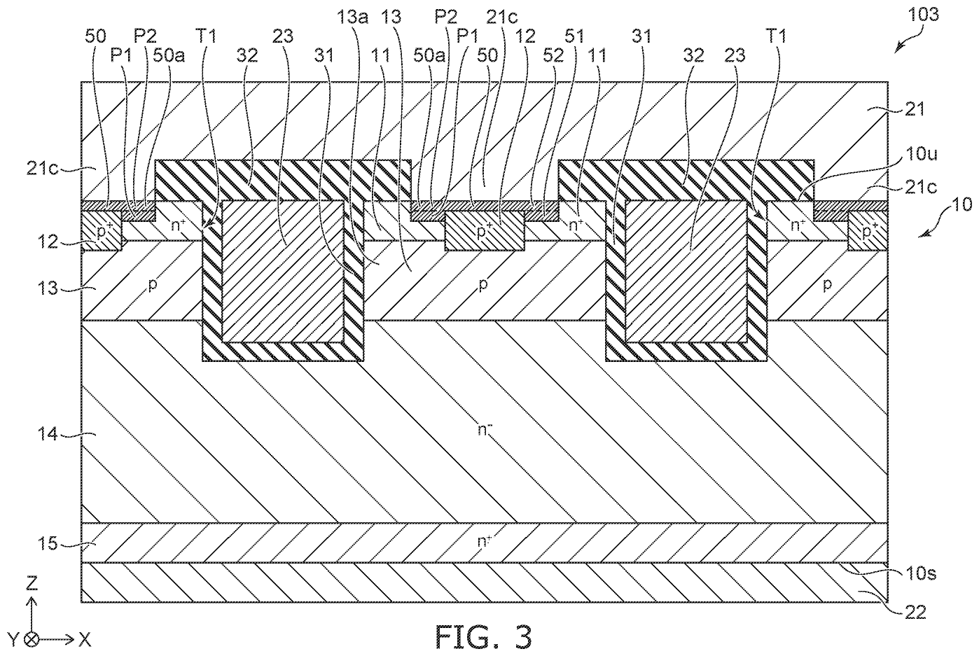

FIG. 3 is a schematic cross-sectional view illustrating a semiconductor device according to a modification of the embodiment.

The arrangement of the control electrode 23 of the semiconductor device 103 according to the embodiment illustrated in FIG. 3 is different from that of the semiconductor device 101 described with reference to FIG. 1.

In the semiconductor device 103, multiple trenches T1 are provided in the upper surface 10u of the semiconductor layer 10. The insulating film 31 is located on the inner surface (the side surface and bottom surface) of the trench T1. The control electrode 23 is located at the inner side of the insulating film 31 of the trench T1. The control electrode 23 is arranged with the source region 11, the body region 13, and the drift region 14 in the X-direction. The insulating film 31 is located between the control electrode 23 and the source region 11, between the control electrode 23 and the body region 13, and between the control electrode 23 and the drift region 14. Thus, for example, the control electrode 23 may be provided as a trench gate.

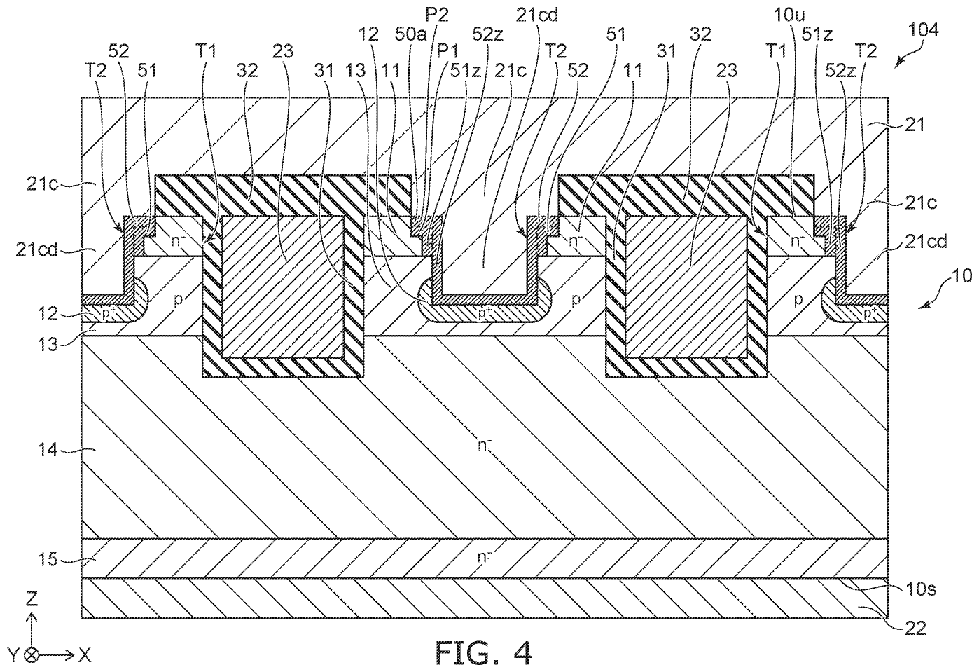

FIG. 4 is a schematic cross-sectional view illustrating a semiconductor device according to a modification of the embodiment.

The arrangement of the contact portion 21c, the connection region 50, the contact region 12, etc., of the semiconductor device 104 according to the embodiment illustrated in FIG. 4 is different from that of the semiconductor device 103 described with reference to FIG. 3.

In the semiconductor device 104, multiple trenches T2 are provided in the upper surface 10u of the semiconductor layer 10. For example, the trench T1 and the trench T2 are alternately arranged in the X-direction. A lower portion 21cd of the contact portion 21c is located inside the trench T2. Therefore, the lower portion 21cd of the contact portion 21c is positioned lower than the upper surface 10u of the semiconductor layer 10 and is arranged in the X-direction with the control electrode 23, the source region 11, and the body region 13. The contact region 12 is located on a portion of the body region 13 at the bottom portion of the trench T2. Therefore, in the example, the contact region 12 is positioned lower than the source region 11 and may not contact the source region 11. The lower portion 21cd of the contact portion 21c is positioned on the contact region 12 with the second region 52 interposed. The first region 51 and the second region 52 respectively include a part 51z and a part 52z extending in the Z-direction along the side surface of the lower portion 21cd of the contact portion 21c. Thus, for example, the contact portion 21c may be provided as a trench contact.

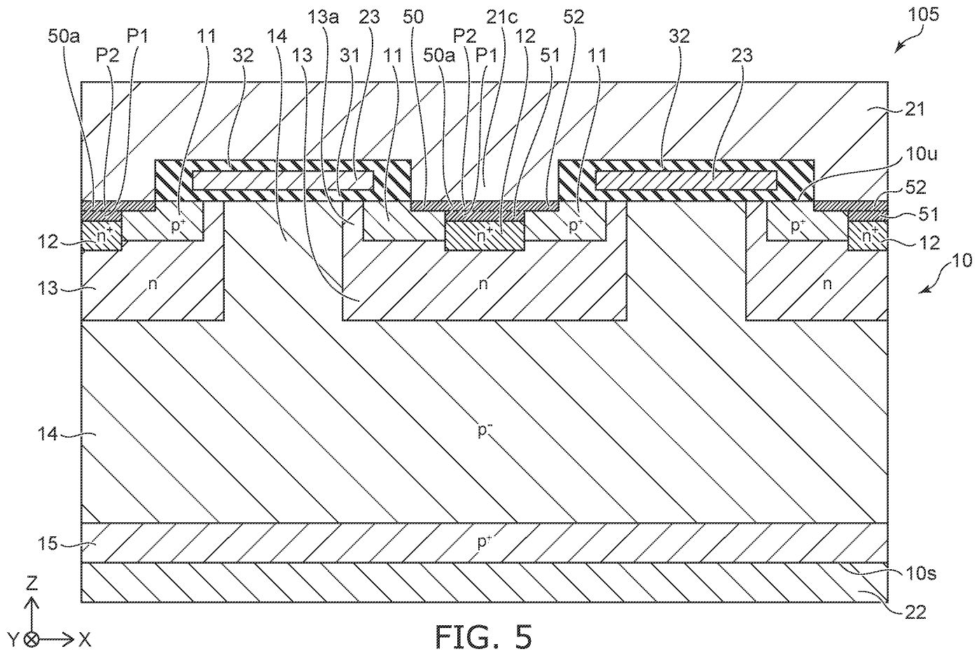

FIG. 5 is a schematic cross-sectional view illustrating a semiconductor device according to a modification of the embodiment.

The semiconductor device 105 according to the embodiment illustrated in FIG. 5 is an example in which the p-type and the n-type of the semiconductor regions are inverted in the semiconductor device 101 described with reference to FIG. 1. In other words, in the semiconductor devices 101 to 104, the first conductivity type is the n-type, and the second conductivity type is the p-type. In contrast, in the semiconductor device 105, the first conductivity type is the p-type, and the second conductivity type is the n-type. The semiconductor device 105 is, for example, a p-channel MOSFET. The arrangement of the first region 51 of the semiconductor device 105 is different from that of the semiconductor device 101 according to the arrangement of the n-type semiconductor regions and the p-type semiconductor regions.

In a p-channel MOSFET, the semiconductor layer 10 includes the multiple source regions 11 (the first semiconductor regions), the multiple contact regions 12 (the fourth semiconductor regions), the multiple body regions 13 (the second semiconductor regions), the drift region 14 (the third semiconductor region), and the drain region 15 (the fifth semiconductor region).

The source region 11 is of the p-type (e.g., a p⁺-type source region). The contact region 12 is of the n-type (e.g., an n⁺-type region). The body region 13 is of the n-type (e.g., an n-type body region). The drift region 14 is of the p-type (e.g., a p⁻-type drift region). The drain region 15 is of the p-type (e.g., a p⁺-type drain region).

As illustrated in FIG. 5, the connection region 50 includes the first part 50a that is adjacent in the first direction (e.g., the Z-direction) to an n-type region of the semiconductor layer 10. For example, the first part 50a is adjacent in the first direction to one of the source region 11 or the contact region 12 that is of the n-type (in the example, the contact region 12). In other words, in the example, the first part 50a is a part of the connection region 50 between the contact region 12 and the first electrode 21. The first part 50a is a part of the connection region 50 that is positioned directly above the contact region 12 and contacts the contact region 12.

At least a portion of the first region 51 is positioned between the contact region 12 and the first electrode 21 and contacts the contact region 12. For example, the first region 51 (the first silicide) has a Schottky contact with the contact region 12. A portion of the second region 52 is positioned between the first region 51 and the first electrode 21 and contacts the first region 51 and the first electrode 21.

For example, the first region 51 may be formed only on an n-type semiconductor region (in the example, the contact region 12) and may not be formed on a p-type semiconductor region (in the example, the source region 11). However, the first region 51 may contact the source region 11.

The multiple first regions 51 are located respectively on the multiple contact regions 12. The second region 52 is provided continuously on two source regions 11 arranged in the X-direction and on the first region 51 positioned between the two source regions 11. One contact portion 21c contacts the upper surface of one second region 52. Thus, a portion of the second region 52 is positioned between the source region 11 and the first electrode 21 and contacts the source region 11 and the first electrode 21. For example, the second region 52 (the second silicide) has a Schottky contact with the source region 11. The second region 52 may or may not contact an n-type semiconductor region (in the example, the contact region 12).

For example, the peak position (the first position P1) of the concentration distribution of the first metallic element in the first direction of the first part 50a of the connection region 50 is between the n-type contact region 12 and the peak position (the second position P2) of the concentration distribution of Pt in the first direction of the first part 50a. In such a case, the contact region 12 is prevented from contacting the second silicide; and the formation of a high energy barrier between the contact region 12 and the second silicide is suppressed. The increase of the contact resistance can be suppressed thereby.

When the n-type contact region 12 contacts the first region 51 (e.g., the first silicide), the increase of the electrical resistance between the contact region 12 and the first region 51 can be suppressed because the energy barrier between the n-type semiconductor region and the first silicide is relatively low. In other words, the increase of the contact resistance can be suppressed. When the p-type source region 11 contacts the second region 52 (e.g., the second silicide), the increase of the electrical resistance between the source region 11 and the second region 52 can be suppressed because the energy barrier between the p-type semiconductor region and the second silicide is relatively low.

Thus, in the semiconductor devices according to the embodiment, the p-type and the n-type of each semiconductor region may be inverted. In such a case, the first region 51 is provided to be adjacent to the n-type semiconductor region.

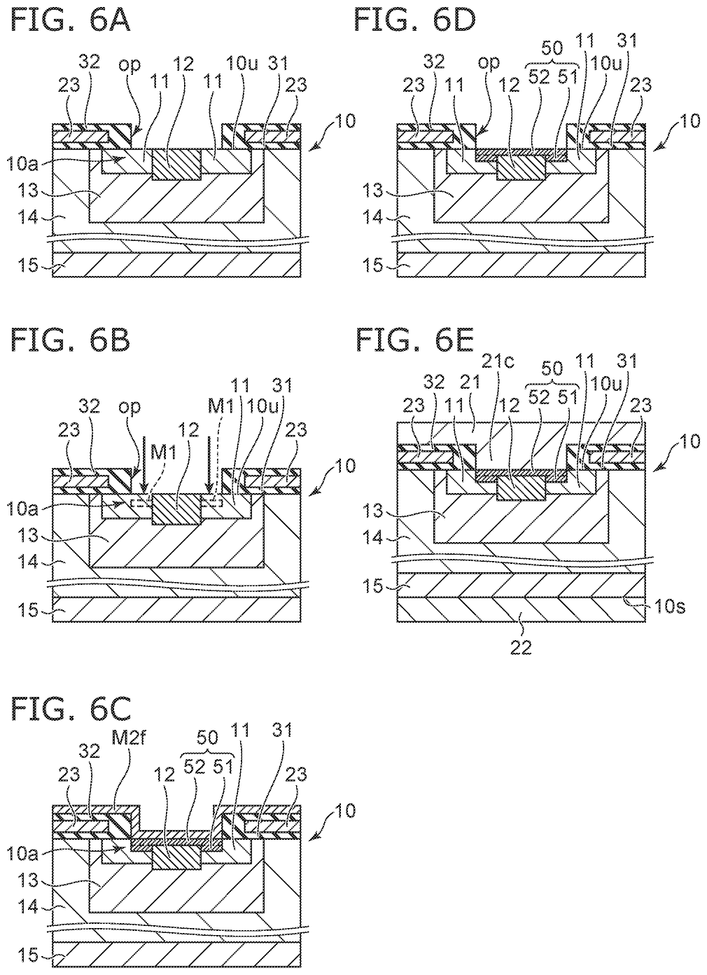

FIGS. 6A to 6E are schematic cross-sectional views in order of the processes, illustrating a method for manufacturing the semiconductor device according to the embodiment.

FIGS. 6A to 6E illustrate manufacturing processes of the semiconductor device 101 described with reference to FIG. 1.

The semiconductor layer 10 is prepared as illustrated in FIG. 6A. The semiconductor layer 10 includes the source region 11, the contact region 12, the body region 13, the drift region 14, and the drain region 15. The insulating film 31, the control electrode 23, and the insulating film 32 are located on the upper surface 10u of the semiconductor layer 10. An opening OP that is positioned above the source region 11 and the contact region 12 is formed in the insulating films 32 and 31. In other words, the insulating film 32 and the insulating film 31 are not formed on a surface layer region 10a of the semiconductor layer 10 that includes a portion of the source region 11 and a portion of the contact region 12. The upper surface 10u of the semiconductor layer 10 (the upper surface of the surface layer region 10a) may be exposed upward via the opening OP.

Subsequently, the first metallic element is implanted into at least a portion of the surface layer region 10a of the semiconductor layer 10. For example, as illustrated in FIG. 6B, a first metallic element M1 is ion-implanted via the opening OP into a part of an n-type semiconductor region (the source region 11) of the surface layer region 10a. For example, the first metallic element M1 is not implanted into a p-type semiconductor region (the contact region 12) of the surface layer region 10a by forming a mask on the p-type semiconductor region by using photolithography, etc. However, the first metallic element M1 may be implanted over the entire region of the opening OP without forming a mask.

Subsequently, the second metallic element is deposited on the surface layer region 10a of the semiconductor layer 10. For example, as illustrated in FIG. 6C, a film M2f that includes the second metallic element is formed by sputtering on the surface layer region 10a and on the insulating film 32. Accordingly, the second metallic element is introduced to a region of the surface layer region 10a that is higher than the position into which the first metallic element M1 is implanted.

Subsequently, as illustrated in FIG. 6D, the film M2f is removed using, for example, aqua regia and/or diluted hydrofluoric acid; and the surface is cleaned. Then, the second metallic element that is introduced to the surface layer region 10a is diffused inside the semiconductor layer 10 by heat treatment.

In the surface layer region 10a, the heat causes a reaction of the semiconductor layer 10 and the first metallic element and a reaction of the semiconductor layer 10 and the second metallic element; and the connection region 50 is formed. In the example, the first region 51 (the first silicide) and the second region 52 (the second silicide) are formed by the heat of the sputtering process of FIG. 6C (and the heat of the diffusion process of FIG. 6D). A heat treatment process for forming the silicides may be provided as necessary.

Subsequently, as illustrated in FIG. 6E, the first electrode 21 is formed on the connection region 50 by, for example, sputtering, etc. For example, the second electrode 22 is formed at the lower surface of the semiconductor layer 10 by sputtering, etc.

The method of introducing the second metallic element to the surface layer region 10a is not limited to a method of depositing the film M2f including the second metallic element; for example, an implantation method may be used in which the second metallic element is implanted into a region of the surface layer region 10a that is higher than the position into which at least a portion of the first metallic element M1 is implanted. For example, instead of processes of depositing and removing the film M2f, the second metallic element may be ion-implanted via the opening OP into a position inside the surface layer region 10a that is shallower than at least a portion of the first metallic element M1.

The embodiments may include the following configurations.

### Configuration 1

A semiconductor device, comprising:
a semiconductor layer including
   a first semiconductor region of a first conductivity type,
   a second semiconductor region contacting the first semiconductor region, the second semiconductor region being of a second conductivity type, and
   a third semiconductor region located so that a portion of the second semiconductor region is positioned between the first semiconductor region and the third semiconductor region, the third semiconductor region being of the first conductivity type;
a first electrode electrically connected with the first semiconductor region;
a second electrode electrically connected with the third semiconductor region;
a control electrode facing the first, second, and third semiconductor regions via an insulating film; and
a connection region positioned between the first electrode and the first semiconductor region,
the connection region electrically connecting the first electrode and the first semiconductor region,
the connection region including
   a compound of a first metallic element and Si, the first metallic element being at least one selected from the group consisting of Ti, V, Cr, Zr, Mo, Hf, Ta, and W, and
   a compound of Pt and Si,
the connection region including a first part adjacent to an n-type region of the semiconductor layer in a first direction,
a peak position of a concentration distribution of the first metallic element in the first direction of the first part being between the n-type region and a peak position of a concentration distribution of Pt in the first direction of the first part.

### Configuration 2

The semiconductor device according to Configuration 1, wherein
the first conductivity type is an n-type,
the second conductivity type is a p-type, and
the first part is between the first semiconductor region and the first electrode.

### Configuration 3

The semiconductor device according to Configuration 2, wherein
the connection region includes:
   a first region including the compound of the first metallic element and Si, at least a portion of the first region being positioned between the first semiconductor region and the first electrode and being in contact with the first semiconductor region; and
   a second region including the compound of Pt and Si, at least a portion of the second region being positioned between the first region and the first electrode and being in contact with the first electrode.

### Configuration 4

The semiconductor device according to any one of Configurations 1 to 3, further comprising:
a fourth semiconductor region of the second conductivity type,
the second semiconductor region contacting the fourth semiconductor region, and having a lower second-conductivity-type impurity concentration than the fourth semiconductor region,
the connection region being positioned between the first electrode and the fourth semiconductor region,
the connection region electrically connecting the first electrode and the fourth semiconductor region.

### Configuration 5

The semiconductor device according to Configuration 3, further comprising:
a fourth semiconductor region of the second conductivity type,
the second semiconductor region contacting the fourth semiconductor region, and having a lower second-conductivity-type impurity concentration than the fourth semiconductor region,
the connection region being positioned between the first electrode and the fourth semiconductor region,
the connection region electrically connecting the first electrode and the fourth semiconductor region,
the fourth semiconductor region contacting the second region.

### Configuration 6

The semiconductor device according to Configuration 1, further comprising:
a fourth semiconductor region of the second conductivity type,
the second semiconductor region contacting the fourth semiconductor region, and having a lower second-conductivity-type impurity concentration than the fourth semiconductor region,
the connection region being positioned between the first electrode and the fourth semiconductor region,
the connection region electrically connecting the first electrode and the fourth semiconductor region,
the first conductivity type being a p-type,
the second conductivity type being an n-type,
the first part being between the fourth semiconductor region and the first electrode.

### Configuration 7

The semiconductor device according to Configuration 6, wherein
the connection region includes:
   a first region including the compound of the first metallic element and Si, at least a portion of the first region being positioned between the fourth semiconductor region and the first electrode and being in contact with the fourth semiconductor region; and
   a second region including the compound of Pt and Si, at least a portion of the second region being positioned between the first region and the first electrode and being in contact with the first electrode.

### Configuration 8

The semiconductor device according to Configuration 7, wherein
the first semiconductor region contacts the second region.

### Configuration 9

A semiconductor device, comprising:
a semiconductor layer including
   a first semiconductor region of a first conductivity type,
   a second semiconductor region contacting the first semiconductor region, the second semiconductor region being of a second conductivity type, and
   a third semiconductor region located so that a portion of the second semiconductor region is positioned between the first semiconductor region and the third semiconductor region, the third semiconductor region being of the first conductivity type;
a first electrode electrically connected with the first semiconductor region;
a second electrode electrically connected with the third semiconductor region;
a control electrode facing the first, second, and third semiconductor regions via an insulating film; and
a connection region positioned between the first electrode and the first semiconductor region,
the connection region electrically connecting the first electrode and the first semiconductor region,
the connection region including
   a compound of a first metallic element and Si, the first metallic element being at least one selected from the group consisting of Ti, V, Cr, Zr, Mo, Hf, Ta, and W, and
   a compound of Pt and Si,
the connection region including
   a first region contacting an n-type region of the semiconductor layer, the first region including the first metallic element, and
   a second region contacting the first electrode, the second region including Pt, the second region not including the first metallic element or having a lower first metallic element concentration than the first region.

### Configuration 10

A method for manufacturing a semiconductor device, the method comprising:
preparing a semiconductor layer, the semiconductor layer including
   a first semiconductor region of a first conductivity type,
   a second semiconductor region contacting the first semiconductor region, the second semiconductor region being of a second conductivity type, and
   a third semiconductor region located so that a portion of the second semiconductor region is positioned between the first semiconductor region and the third semiconductor region, the third semiconductor region being of the first conductivity type, a control electrode facing the second and third semiconductor regions via an insulating film;
implanting a first metallic element into at least a portion of a surface layer region of the semiconductor layer, the surface layer region including a portion of the first semiconductor region, the first metallic element being at least one selected from the group consisting of Ti, V, Cr, Zr, Mo, Hf, Ta, and W;
depositing Pt on the surface layer region, or implanting Pt into a region of the surface layer region higher than a position into which at least a portion of the first metallic element is implanted;
forming a first electrode on a connection region, the connection region being formed by reacting the semiconductor layer and the first metallic element and reacting the semiconductor layer and Pt in the surface layer region, the first electrode being electrically connected with the first semiconductor region; and
forming a second electrode electrically connected with the third semiconductor region.

According to embodiments, a semiconductor device and a method for manufacturing a semiconductor device can be provided in which the increase of the contact resistance can be suppressed.

In the embodiments above, the relative levels of the impurity concentrations between the semiconductor regions can be confirmed using, for example, a SCM (scanning capacitance microscope). The carrier concentration in each semiconductor region can be considered to be equal to the activated impurity concentration in each semiconductor region. Accordingly, the relative levels of the carrier concentrations between the semiconductor regions also can be confirmed using SCM. The relative levels of the impurity concentrations between the semiconductor regions can be considered to correspond to the relative levels of the carrier concentrations between the semiconductor regions. Also, the impurity concentration in each semiconductor region can be measured by, for example, SIMS (secondary ion mass spectrometry).

When both an impurity that forms donors and an impurity that forms acceptors are included in a region, the “impurity concentration” may be the net impurity concentration after the impurities have canceled.

In this specification, being “electrically connected” includes not only the case of being connected in direct contact, but also the case of being connected via another conductive member, etc.

The scope of one component being “located on” another component may include not only the case where the two components contact each other (or are continuous), but also the case where another component is located between the two components. For example, the scope of one component being “located on” another component may include the case where one component is positioned above another component regardless of whether or not the two components contact each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a semiconductor layer including
a first semiconductor region of a first conductivity type,
a second semiconductor region contacting the first semiconductor region, the second semiconductor region being of a second conductivity type, and
a third semiconductor region located so that a portion of the second semiconductor region is positioned between the first semiconductor region and the third semiconductor region, the third semiconductor region being of the first conductivity type;
a first electrode electrically connected with the first semiconductor region;
a second electrode electrically connected with the third semiconductor region;
a control electrode facing the first, second, and third semiconductor regions via an insulating film; and
a connection region positioned between the first electrode and the first semiconductor region,
the connection region electrically connecting the first electrode and the first semiconductor region,
the connection region including
a compound of a first metallic element and Si, the first metallic element being at least one selected from the group consisting of Ti, V, Cr, Zr, Mo, Hf, Ta, and W, and
a compound of Pt and Si,
the connection region including a first part adjacent to an n-type region of the semiconductor layer in a first direction,
a peak position of a concentration distribution of the first metallic element in the first direction of the first part being between the n-type region and a peak position of a concentration distribution of Pt in the first direction of the first part.

2. The semiconductor device according to claim 1, wherein
the first conductivity type is an n-type,
the second conductivity type is a p-type, and
the first part is between the first semiconductor region and the first electrode.

3. The semiconductor device according to claim 2, wherein
the connection region includes:
a first region including the compound of the first metallic element and Si, at least a portion of the first region being positioned between the first semiconductor region and the first electrode and being in contact with the first semiconductor region; and
a second region including the compound of Pt and Si, at least a portion of the second region being positioned between the first region and the first electrode and being in contact with the first electrode.

4. The semiconductor device according to claim 1, further comprising:
a fourth semiconductor region of the second conductivity type,
the second semiconductor region contacting the fourth semiconductor region, and having a lower second-conductivity-type impurity concentration than the fourth semiconductor region,
the connection region being positioned between the first electrode and the fourth semiconductor region,
the connection region electrically connecting the first electrode and the fourth semiconductor region.

5. The semiconductor device according to claim 3, further comprising:
a fourth semiconductor region of the second conductivity type,
the second semiconductor region contacting the fourth semiconductor region, and having a lower second-conductivity-type impurity concentration than the fourth semiconductor region,
the connection region being positioned between the first electrode and the fourth semiconductor region,
the connection region electrically connecting the first electrode and the fourth semiconductor region,
the fourth semiconductor region contacting the second region.

6. The semiconductor device according to claim 1, further comprising:
a fourth semiconductor region of the second conductivity type,
the second semiconductor region contacting the fourth semiconductor region, and having a lower second-conductivity-type impurity concentration than the fourth semiconductor region,
the connection region being positioned between the first electrode and the fourth semiconductor region,
the connection region electrically connecting the first electrode and the fourth semiconductor region,
the first conductivity type being a p-type,
the second conductivity type being an n-type,
the first part being between the fourth semiconductor region and the first electrode.

7. The semiconductor device according to claim 6, wherein
the connection region includes:
a first region including the compound of the first metallic element and Si, at least a portion of the first region being positioned between the fourth semiconductor region and the first electrode and being in contact with the fourth semiconductor region; and
a second region including the compound of Pt and Si, at least a portion of the second region being positioned between the first region and the first electrode and being in contact with the first electrode.

8. The semiconductor device according to claim 7, wherein
the first semiconductor region contacts the second region.

9. A semiconductor device, comprising:
a semiconductor layer including
a first semiconductor region of a first conductivity type,
a second semiconductor region contacting the first semiconductor region, the second semiconductor region being of a second conductivity type, and
a third semiconductor region located so that a portion of the second semiconductor region is positioned between the first semiconductor region and the third semiconductor region, the third semiconductor region being of the first conductivity type;
a first electrode electrically connected with the first semiconductor region;
a second electrode electrically connected with the third semiconductor region;
a control electrode facing the first, second, and third semiconductor regions via an insulating film; and
a connection region positioned between the first electrode and the first semiconductor region,
the connection region electrically connecting the first electrode and the first semiconductor region,
the connection region including
a compound of a first metallic element and Si, the first metallic element being at least one selected from the group consisting of Ti, V, Cr, Zr, Mo, Hf, Ta, and W, and
a compound of Pt and Si,
the connection region including
a first region contacting an n-type region of the semiconductor layer, the first region including the first metallic element, and
a second region contacting the first electrode, the second region including Pt, the second region not including the first metallic element or having a lower first metallic element concentration than the first region.

10. A method for manufacturing a semiconductor device, the method comprising:
preparing a semiconductor layer, the semiconductor layer including
a first semiconductor region of a first conductivity type,
a second semiconductor region contacting the first semiconductor region, the second semiconductor region being of a second conductivity type, and
a third semiconductor region located so that a portion of the second semiconductor region is positioned between the first semiconductor region and the third semiconductor region, the third semiconductor region being of the first conductivity type, a control electrode facing the second and third semiconductor regions via an insulating film;
implanting a first metallic element into at least a portion of a surface layer region of the semiconductor layer, the surface layer region including a portion of the first semiconductor region, the first metallic element being at least one selected from the group consisting of Ti, V, Cr, Zr, Mo, Hf, Ta, and W;
depositing Pt on the surface layer region, or implanting Pt into a region of the surface layer region higher than a position into which at least a portion of the first metallic element is implanted;
forming a first electrode on a connection region, the connection region being formed by reacting the semiconductor layer and the first metallic element and reacting the semiconductor layer and Pt in the surface layer region, the first electrode being electrically connected with the first semiconductor region; and
forming a second electrode electrically connected with the third semiconductor region.
